(19) United States
(12) Patent Application Publication
(10) Pub. No.: US 2026/0031301 A1
(43) Pub. Date: Jan. 29, 2026

(54) PATTERN INSPECTION SYSTEM AND METHOD OF PATTERN INSPECTION USING THE SAME

(71) Applicant: SAMSUNG ELECTRONICS CO., LTD., Suwon-si (KR)

(72) Inventors: Jinwoo LEE, Suwon-si (KR); Bumjoo LEE, Suwon-si (KR); Yusin YANG, Suwon-si (KR); Sunghoon PARK, Suwon-si (KR); Jongcheon SUN, Suwon-si (KR); Su-Young LEE, Suwon-si (KR)

(73) Assignee: SAMSUNG ELECTRONICS CO., LTD., Suwon-si (KR)

(21) Appl. No.: 19/013,860

(22) Filed: Jan. 8, 2025

(30) Foreign Application Priority Data
Jul. 24, 2024 (KR) 10-2024-0097968

(51) Int. Cl. H01J 37/28; H01J 37/26

(52) U.S. Cl. CPC H01J 37/28; H01J 37/261; H01J 2237/223; H01J 2237/2817

(57) ABSTRACT

Provided is a pattern inspection system, including a scanning electron microscope (SEM) including an electron gun configured to generate a first electron beam and emit the generated first electron beam toward a first wafer, a detector configured to detect electrons emitted from the first wafer based on the first electron beam emitted toward the first wafer, and at least one processor configured to generate a first SEM image including a plurality of pixels based on the detected electrons, and determine, based on a period of a pattern extracted from the first SEM image, a pixel size of a second SEM image to be generated by the SEM with respect to a second wafer.

### CROSS-REFERENCE TO RELATED APPLICATION

This application claims priority to Korean Patent Application No. 10-2024-0097968, filed in the Korean Intellectual Property Office on Jul. 24, 2024, the disclosure of which is incorporated herein in its entirety by reference.

### BACKGROUND

Embodiments of the present disclosure relate to a pattern inspection system and a method of pattern inspection using the same.

A scanning electron microscope (SEM) can analyze topographical information of the shape of a sample surface, morphological information such as the shape and size of the particles in the sample, or crystallographic information such as arrangement of atoms in the sample.

SEM has made it possible to observe microstructures that are unmeasurable due to resolution limitations of the optical microscopes, and accordingly, SEM is applied to a wide range of fields such as medicine, biotechnology, biology, microorganisms, material engineering, food engineering and others. In particular, with the development of a low vacuum SEM that can observe images under low vacuum conditions, the application of the SEM is expanding.

However, existing analysis methods using SEM have relatively low throughput, and may have a problem that nuisance defects caused by aliasing appear in SEM images.

### SUMMARY

One or more embodiments provide a pattern inspection system and a method of pattern inspection using the same.

According to an aspect of one or more embodiments, there is provided a pattern inspection system, including a scanning electron microscope (SEM) including an electron gun configured to generate a first electron beam and emit the generated first electron beam toward a first wafer, a detector configured to detect electrons emitted from the first wafer based on the first electron beam emitted toward the first wafer, and at least one processor configured to generate a first SEM image including a plurality of pixels based on the detected electrons, and determine, based on a period of a pattern extracted from the first SEM image, a pixel size of a second SEM image to be generated by the SEM with respect to a second wafer.

According to another aspect of one or more embodiments, there is provided a computing device, including a memory configured to store one or more instructions, and at least one processor configured to execute the one or more instructions stored in the memory to receive a first scanning electron microscope (SEM) image from a scanning electron microscope configured to detect electrons emitted from a first wafer based on electron beam being emitted onto the first wafer, generate a first SEM image including a plurality of pixels based on the detected electrons, and determine, based on a period of a pattern extracted from the first SEM image, a pixel size of a second SEM image with respect to a second wafer to be generated by the SEM.

According to still another aspect of one or more embodiments, there is provided a method of pattern inspection, the method being executed by at least one processor, the method including receiving a first scanning electron microscope (SEM) image from a scanning electron microscope configured to detect electrons emitted from a first wafer based on first electron beam being emitted onto the first wafer, generating a first SEM image including a plurality of pixels based on the detected electrons, and determining, based on a period of a pattern extracted from the first SEM image, a pixel size of a second SEM image with respect to a second wafer to be generated by the SEM . . .

### BRIEF DESCRIPTION OF DRAWINGS

The above and other objects, features and advantages of the present disclosure will become more apparent to those of ordinary skill in the art by describing in detail embodiments thereof with reference to the accompanying drawings, in which:

FIG. 1 is a diagram illustrating a scanning electron microscope according to one or more embodiments;

FIG. 2 is a diagram illustrating an example of an SEM image generated using an SEM according to one or more embodiments;

FIG. 3 is a block diagram illustrating an internal configuration of a pattern inspection system according to one or more embodiments;

FIG. 4 is a flowchart illustrating a method for generating an SEM image according to one or more embodiments;

FIG. 5 is a flowchart illustrating a method for determining a size of a pixel of an SEM image and generating an SEM image according to one or more embodiments;

FIG. 6 is a diagram illustrating an operation S530 of FIG. 5 in more detail;

FIG. 7 is a diagram provided to explain operation S610 of FIG. 6, which illustrates an example in which an input electron beam is irradiated (emitted) onto a partial area of a wafer;

FIG. 8 is a graph provided to explain operation S610 of FIG. 6, which illustrates a full width at half maximum of the input electron beam;

FIGS. 9A and 9B show fast Fourier transform (FFT) image and graph illustrating operations S620 and S630 of FIG. 6;

FIG. 10 is a diagram illustrating a scan direction of the wafer using the SEM according to one or more embodiments;

FIGS. 11A, 11B, and 11C are diagrams illustrating SEM images including different pixel sizes according to one or more embodiments; and

FIG. 12 is a graph comparing the number of defects before and after determining a pixel size according to one or more embodiments.

### DETAILED DESCRIPTION

Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

In the present disclosure, a ‘size’ of a pixel included in an image may refer to a length of one side of the pixel or a length in a real space represented by one side of the pixel.

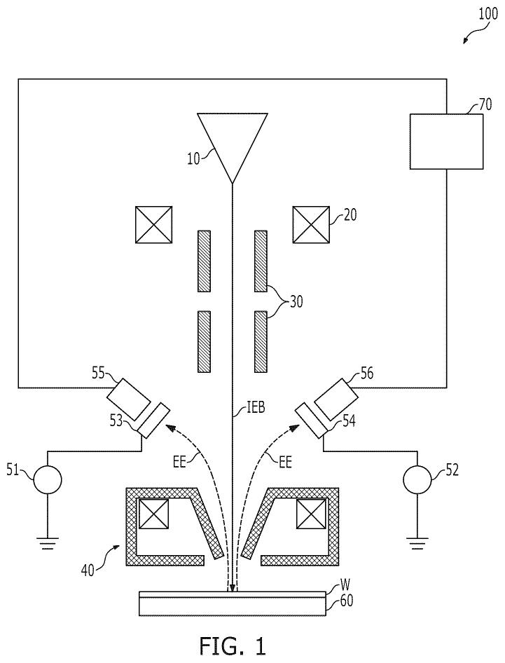

FIG. 1 is a diagram illustrating a scanning electron microscope (SEM) 100 according to some aspects.

The SEM 100 may be configured to measure a wafer W. According to one or more embodiments, the SEM 100 may measure the wafer W, which has undergone a semiconductor device manufacturing process, using a scanning method. According to one or more embodiments, the SEM 100 may obtain, by measuring the wafer W, topographical information of the wafer W, morphological information such as the shape and size of particles in the wafer W, or crystallographic information such as an arrangement of atoms in the wafer W.

According to one or more embodiments, the SEM 100 may evaluate the semiconductor device manufacturing process performed on the wafer W by irradiating (emitting) an input electron beam IEB onto the wafer W and detecting electrons EE emitted from the wafer W due to the interaction between the input electron beam IEB and the wafer W. The electrons EE may be generated by elastic scattering or may be generated by inelastic scattering.

Elastic scattering is a phenomenon in which electrons included in the input electron beam IEB are directed in an opposite direction to an input direction of the input electron beam IEB without substantial changes in the energy of electrons included in the input electron beam IEB due to the potential of the atomic nuclei constituting the wafer W. Electrons escaping from the surface of the wafer W by elastic scattering may be referred to as backscattered electrons, and backscattered electrons may have an energy of greater than or equal to about 50 eV. The detection result of the backscattered electrons may include information on the structure near the surface of the wafer W and information on the composition.

Inelastic scattering may refer to a phenomenon in which electrons contained in the atoms of the wafer W are emitted due to interactions with electrons in the electron orbit of atoms in the wafer W when electrons included in the input electron beam IEB strike the surface of the wafer W. Secondary electrons, Auger electrons, and X-rays may be emitted due to the inelastic scattering. The secondary electrons of the electrons EE may have an energy of about a few eV. The detection result of the secondary electrons may include information on irregularities near the surface of the wafer W.

The secondary electrons may be the result of energy being transferred to electrons bound to atoms in the wafer W by electrons included in the input electron beam IEB, causing the bound electrons to be emitted as free electrons. When electrons at a relatively low energy level other than the valence band are emitted as secondary electrons, electrons at a high energy level may move to a low energy level, emitting X-rays, and electrons excited by X-rays and emitted from the wafer W may be Auger electrons. The X-ray may include continuum X-rays and characteristic X-rays. The detection result of the Auger electrons and X-ray may include information on the composition and chemical bonding near the surface of the wafer W.

The SEM 100 may further detect signals from incoherent elastic scattering, transmitted electrons, and cathodoluminescence.

The SEM 100 may include an electron gun 10, a focusing lens 20, a deflector 30, an objective lens 40, a first power source 51, a second power source 52, a first energy filter 53, a second energy filter 54, a first detector 55, a second detector 56, a stage 60, and a processor 70. The configuration of the SEM 100 is not limited to those illustrated, and some of the illustrated components may be omitted or additional components may be further included.

The electron gun 10 may generate and emit the input electron beam IEB. The wavelength of the input electron beam IEB may be determined by the energy of electrons emitted from the electron gun 10. According to one or more embodiments, the wavelength of the input electron beam IEB may be several nanometers (nm). According to one or more embodiments, the electron gun 10 may be, for example, a cold field emission (CFE) type, a Schottky emission (SE) type, or a thermionic emission (TE) type.

The electron gun 10 may generate the input electron beam IEB by thermally or electrically applying energy above a work function (i.e., the difference between the energy level and the Fermi energy in a vacuum) to electrons included in a solid material as an electron source.

The focusing lens 20 may be disposed on the path of the input electron beam IEB between the electron gun 10 and the wafer W. According to one or more embodiments, the focusing lens 20 may focus the input electron beam IEB onto the deflector 30. Accordingly, the controllability of the input electron beam IEB by the deflector 30 may be improved.

The deflector 30 may be disposed on the path of the input electron beam IEB between the focusing lens 20 and the wafer W. The deflector 30 may deflect the input electron beam IEB emitted from the electron gun 10. The deflector 30 may deflect the input electron beam IEB so that the input electron beam IEB passes through the focusing lens 20 and the objective lens 40 and reaches a set position on the wafer W. According to one or more embodiments, the deflector 30 may scan the input electron beam IEB across the wafer W. The deflector 30 may be either an electric type or a magnetic type.

The objective lens 40 may be disposed on the path of the input electron beam IEB between the deflector 30 and the wafer W. The objective lens 40 may focus the input electron beam IEB on the wafer W. As the input electron beam IEB is limited to a narrow area on the wafer W by the object lens 40, the resolution of the SEM 100 may be further improved.

The transmission system of the input electron beam (IEB) including the focusing lens 20, the deflector 30, and the objective lens 40 has been described, but embodiments are not limited thereto. For example, a transmission system of the input electron beam IEB may include additional focusing lenses and an additional deflector.

The first power source 51 may supply power for filtering the electrons EE to the first energy filter 53. According to one or more embodiments, the first energy filter 53 may be a high-pass filter. According to one or more embodiments, the blocking energy of the first energy filter 53 may be first energy E1. According to one or more embodiments, the first energy filter 53 may block electrons having an energy less than the first energy E1 of the electrons EE.

The second power source 52 may supply power for filtering the electrons EE to the second energy filter 54. According to one or more embodiments, the second energy filter 54 may be a high pass filter. According to one or more embodiments, the blocking energy of the second energy filter 54 may be second energy E2. According to one or more embodiments, the second energy filter 54 may block electrons having an energy less than the second energy E2 of the electrons EE.

According to one or more embodiments, the first energy E1 and the second energy E2 may be different from each other. According to one or more embodiments, the first energy E1 may be less than the second energy E2.

According to one or more embodiments, the first detector 55 may detect some of the electrons EE that have passed through the first energy filter 53. According to one or more embodiments, the energy of the electrons EE detected by the first detector 55 may be greater than or equal to the first energy E1.

According to one or more embodiments, the second detector 56 may detect some of the electrons EE that have passed through the second energy filter 54. According to one or more embodiments, the energy of the electrons EE detected by the second detector 56 may be greater than or equal to the second energy E2.

The stage 60 may support the wafer W to be measured. The stage 60 may move the wafer W in the horizontal and vertical directions or rotate the wafer W about the vertical direction so that the wafer W is aligned with the optical system (i.e., the optical system including the electron gun 10, the focusing lens 20, the deflector 30, and the objective lens 40) that transmits the input electron beam IEB.

The processor 70 may process the first image generated by the first detector 55 and the second image generated by the second detector 56. The processor 70 may perform a difference operation between the first image generated by the first detector 55 and the second image generated by the second detector 56. The processor 70 may obtain a difference image of the wafer W based on the first image generated by the first detector 55 and the second image generated by the second detector 56.

According to one or more embodiments, the SEM 100 may further include a controller configured to control each of the optical elements included in the SEM 100. The controller may be configured to generate a signal for controlling, for example, the emission of the electron gun 10, the operation of the focusing lens 20, the operation of the deflector 30, the operation of the objective lens 40, the operation of the first and second power sources 51 and 52, and accordingly, the operation of the first and second filters 53 and 54.

The controller and/or the processor 70 may be a computing device such as a workstation computer, a desktop computer, a laptop computer, a tablet computer, etc. The controller and the processor 70 may each be configured as separate hardware or they may be separate software included in one hardware. The controller and the processor 70 may be a simple controller, a complex processor such as a microprocessor, a central processing unit (CPU), a graphical processing unit (GPU), etc., a processor configured by software, dedicated hardware, or firmware. The controller and the processor 70 may be implemented by, for example, a general-purpose computer or application-specific hardware such as a digital signal processor (DSP), a field programmable gate array (FPGA), and an application specific integrated circuit (ASIC), etc.

According to one or more embodiments, the operation of the controller and/or the processor 70 may be implemented as instructions stored on a machine-readable medium that may be read and executed by one or more processors. The machine-readable medium may include any mechanism for storing and/or transmitting information in a form readable by a machine (e.g., a computing device). For example, the machine-readable medium may include a Read Only Memory (ROM), a Random Access Memory (RAM), a magnetic disk storage medium, an optical storage medium, a flash memory device, or an electrical, optical, acoustic, or other types of propagated signals (e.g., carrier, infrared signal, digital signal, etc.) and any other signals.

The controller and/or the processor 70 may be configured with firmware, software, routines, and instructions for performing the operation described for the controller and/or the processor 70 or any process described below. However, it should be understood that this is for purposes of illustration only and that the operations of the controller and/or the processor 70 described above may also result from computing devices, processors, controllers, or other devices that execute firmware, software, routines, or instructions, etc.

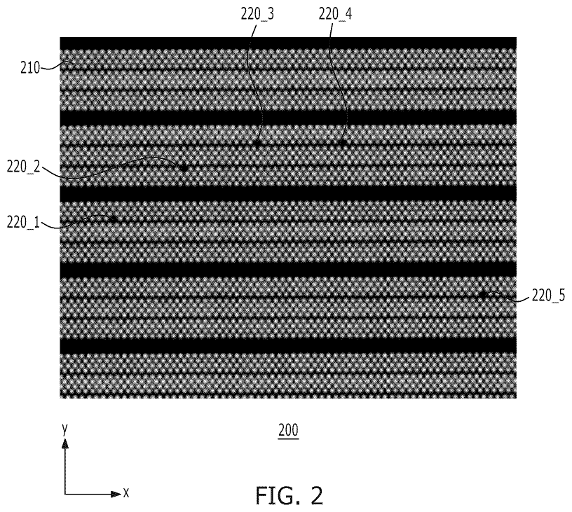

FIG. 2 is a diagram illustrating an example of an SEM image 200 generated using the SEM. The SEM image 200 of FIG. 2 may be an image obtained with an SEM (e.g., 100 in FIG. 1) by irradiating (emitting) an electron beam onto at least a partial area of the wafer that has undergone the semiconductor device manufacturing process and detecting electrons emitted from the area by the electron beam.

The SEM image 200 may include a plurality of pixels. For example, the SEM image 200 may include a plurality of pixels corresponding to a location on the wafer irradiated (emitted) with the input electron beam. As a higher density input electron beam is irradiated (emitted) onto the wafer, more pixels are included in the SEM image 200, and as the resolution of the SEM image 200 increases, the details of the structures or defects on the wafer can be observed more sharply and clearly. For example, the SEM image 200 of FIG. 2 is a high-resolution image in which the size of each of the plurality of pixels corresponds to a length of 20 nm on the wafer, and contacts 210 and defects 220_1, 220_2, 220_2, 220_3, 220_4, and 220_5 on the wafer may be more clearly observed. For example, the defects 220_1 to 220_5 may represent areas where a normal pattern is not formed on the wafer due to factors such as dust introduced from the outside, abnormalities in process facilities, or by-products generated in the process, etc.

Because acquiring the high-resolution SEM image 200 requires a high-density input electron beam be irradiated (emitted) onto the wafer, the time required to generate the SEM image 200 increases, reducing the throughput of the SEM, and increasing the resources and time required to analyze the SEM image 200. Therefore, increasing the throughput of the SEM by reducing the time and resources required to generate the SEM image 200 while minimizing the reduction in the defect detection rate using the SEM image 200 is needed despite a slight reduction in the resolution of the generated SEM image 200.

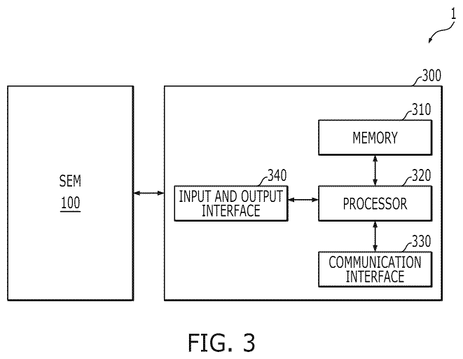

FIG. 3 is a block diagram illustrating an internal configuration of a pattern inspection system 1.

The pattern inspection system 1 may include the SEM 100 illustrated and described with reference to FIG. 1 and a computing device 300. The computing device 300 may be a module connected separately from the SEM 100 to increase the throughput of the SEM 100. Accordingly, it is possible to improve the throughput of the SEM 100 by connecting the SEM 100 with the computing device 300, without changing the structure of the existing SEM 100. According to one or more other embodiments, at least a portion of the computing device 300 may be included in the SEM 100.

The computing device 300 may be connected to the SEM 100 to determine the size of the pixel of the SEM image generated by the SEM 100. For example, the computing device 300 may determine the pixel size of the SEM image generated by the SEM 100 to be greater than the pixel size of the existing SEM image (e.g., 200 in FIG. 2), thereby the time for generating the SEM image may be shortened and the throughput of the SEM 100 may be improved.

The computing device 300 may include a memory 310, a processor 320, a communication interface 330, and an input and output interface 340.

The memory 310 may include any non-transitory computer-readable recording medium. The memory 310 may include a permanent mass storage device such as read only memory (ROM), disk drive, solid state drive (SSD), flash memory, etc. As another example, a non-volatile mass storage device such as ROM, SSD, flash memory, disk drive, etc. may be included in the computing device 300 as a separate permanent storage device that is separate from the memory. In addition, an operating system and at least one program code may be stored in the memory 310. The memory 310 may store one or more instructions associated with the process for determining the size of the pixel of the SEM image.

These software components may be loaded from a computer-readable recording medium separate from the memory 310. Such a separate computer-readable recording medium may include a recording medium directly connectable to the computing device 300, and may include a computer-readable recording medium such as a floppy drive, a disk, a tape, a DVD/CD-ROM drive, a memory card, etc., for example. In another example, the software components may be loaded into the memory 310 through the communication interface 330 rather than from the computer-readable recording medium. For example, at least one program may be loaded into the memory 310 based on a computer program installed by files provided by developers or a file distribution system that distributes an installation file of an application through the communication interface 330.

The processor 320 may be configured to process commands of a computer program stored in the memory 310 by performing basic arithmetic, logic, and input/output operations. The commands may be provided to a user terminal or another external system through the memory 310 or the communication interface 330. In addition, the processor 320 may be configured to manage, process, and/or store information and/or data received from a plurality of user terminals and/or a plurality of external systems.

As illustrated in FIG. 3, the computing device 300 may be configured to communicate information and/or data through a network by using the communication interface 330.

The communication interface 330 may provide a configuration or function for the SEM 100 and the computing device 300 to communicate with each other through a network, and may provide a configuration or function for the computing device 300 to communicate with an external system. For example, control signals, commands, data, etc. provided under the control of the processor 320 of the computing device 300 may be transmitted to the SEM 100 through the communication interface 330 and the network. Likewise, the computing device 300 may receive signals, commands, data, etc. from the SEM 100. The SEM 100 may transmit the SEM image for a specific wafer to the computing device 300, and the computing device 300 may transmit the determined pixel size (or information related thereto) of the SEM image to the SEM 100, so that the SEM 100 may generate an SEM image of a corresponding pixel size.

In addition, the input and output interface 340 of the computing device 300 may interface with a device for input or output which may be connected to or included in the computing device 300. For example, the computing device 300 may receive a minimum size (or information related thereto) of a defect to be detected from a user, etc. using the input/output interface 340. In FIG. 3, the input and output interface 340 is illustrated as a component configured separately from the processor 320, but embodiments are not limited thereto, and the input and output interface 340 may be configured to be included in the processor 320.

The computing device 300 may include more components than those illustrated in FIG. 3.

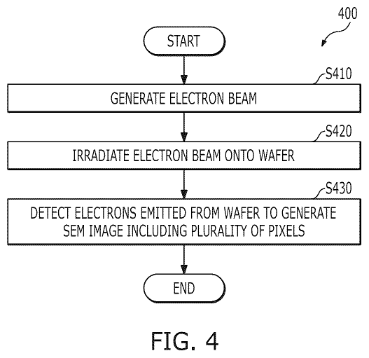

FIG. 4 is a flowchart illustrating a method 400 for generating an SEM image. Each steps of FIG. 4 may be performed by the SEM 100 of FIG. 1.

The SEM 100 may generate an electron beam, at step S410. Referring to FIG. 1, an electron beam may be generated by the electron gun 10 of the SEM 100. According to one or more embodiments, the electron gun 10 may be any one of a cold field emission (CFE) type, an Schottky effect (SE) type, and a thermal field-emission (TE) type. The electron gun 10 may generate an electron beam by thermally or electrically applying an energy greater than or equal to a work function to electrons included in a solid material as an electron source.

The SEM 100 may irradiate (emit) the generated electron beam onto the wafer, at step S420. For example, the SEM 100 may control the electron beam so that the area on the wafer to be irradiated (emitted) with the electron beam moves along a specific scan direction. Referring to FIG. 1, the SEM 100 may focus the electron beam on a narrow area on the wafer W or scan the electron beam across the wafer W, through the focusing lens 20, the deflector 30, and the objective lens 40 arranged between the electron gun 10 and the wafer W.

The SEM 100 may detect electrons emitted from the wafer to generate an SEM image including a plurality of pixels, at step S430. Referring to FIG. 1, the electrons EE may be filtered by the energy filters 53 and 54, and some of the electrons EE that have passed through the filters 53 and 54 may be detected by the detectors 55 and 56 to generate an image. In addition, the processor 70 may process the image generated by the detectors 55 and 56 to generate an SEM image.

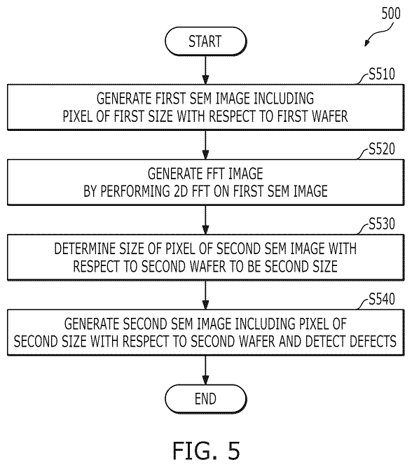

FIG. 5 is a flowchart illustrating a method 500 for determining a size of a pixel of an SEM image and generating an SEM image. The method 500 of FIG. 5 may be performed by the pattern inspection system 1 including the SEM 100 and the computing device 300 of FIG. 3.

The SEM 100 may generate a first SEM image including a pixel of a first size with respect to the first wafer, at step S510. The first SEM image of the first wafer may be generated by the method 400 of FIG. 4. The first wafer may be a reference wafer for determining the size of the pixel of the first SEM image. For example, the first wafer is a wafer used to determine the size of the pixels in the SEM image, and pattern inspection may be performed by generating an SEM image including pixels of the size determined using the first wafer for each of a plurality of wafers (e.g., second wafers) manufactured using the same process.

The computing device 300 may generate an Fast Fourier Transform (FFT) image by performing a 2-Dimension FFT (2D FFT) on the generated first SEM image, at step S520. For example, the SEM 100 may transmit the first SEM image generated at step S510 to the computing device 300. In response to receiving the first SEM image, the computing device 300 (or the communication interface 330) may generate the FFT image using the processor 320 based on the first SEM image. According to one or more other embodiments, step S520 may be performed by the SEM 100.

The computing device 300 (or the processor 320) may determine the size of the pixel of the second SEM image for the second wafer, which is manufactured using the same process as the first wafer, to be a second size, at step S530. The second size may be greater than the first size. Accordingly, the throughput of the SEM 100 may be increased when the pattern inspection is performed on the second wafer.

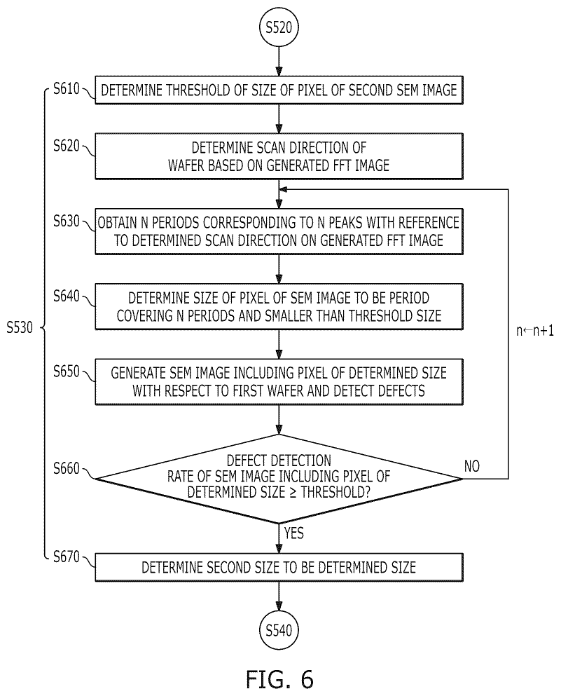

The computing device 300 may determine the size of the pixel of the second SEM image based on a period of the pattern formed on the first SEM image. For example, the computing device 300 may extract the period of the pattern formed on the first SEM image using the FFT image generated at step S520, and determine the size of the pixel of the second SEM image based on the extracted result. The detailed steps and operations for determining the size of the pixel of the second SEM image based on the period of the pattern formed on the first SEM image will be described in detail with reference to FIGS. 6 to 9.

The SEM 100 may generate an SEM image including a pixel of the second size determined at step S530 with respect to the second wafer and detect a defect, at step S540. For example, the computing device 300 may transmit the pixel size determined at step S530 to the SEM 100, and the SEM 100 may generate an SEM image based on the transmitted pixel size. The SEM image of the second wafer may be generated by the method 400 of FIG. 4. According to one or more other embodiments, the operation of detecting a defect from the SEM image may be performed by the computing device 300.

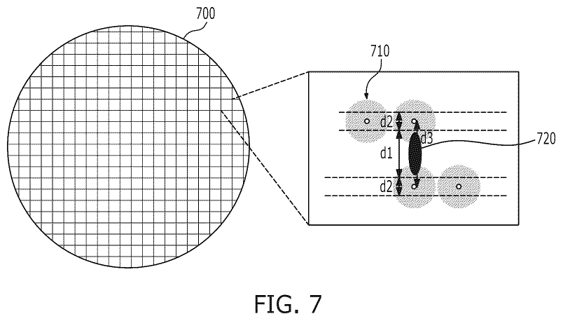

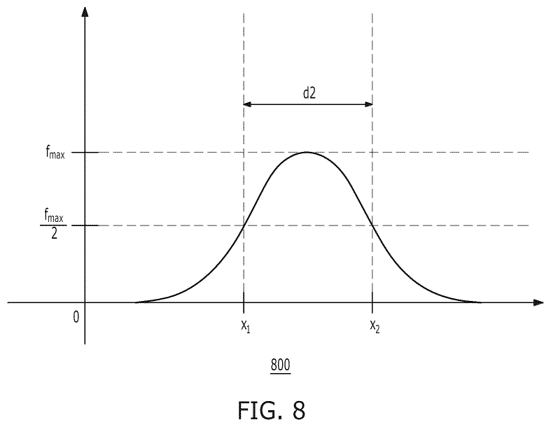

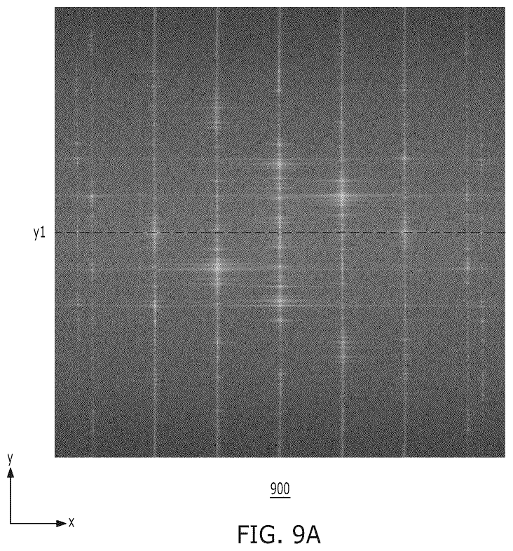

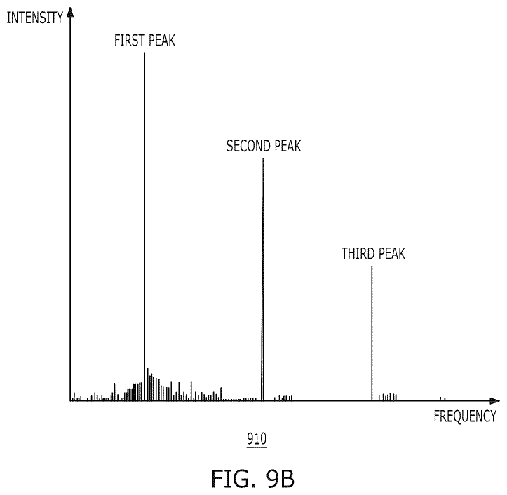

FIG. 6 is a diagram illustrating step S530 of FIG. 5 in more detail, FIG. 7 is a diagram provided to explain the step S610 of FIG. 6, which illustrates an example in which an input electron beam 710 is irradiated (emitted) onto a partial area of a wafer 700, FIG. 8 is a graph 800 provided to explain operation S610 of FIG. 6, which illustrates a full width at half maximum (FWHM) d2 of the input electron beam 710, and FIGS. 9A and 9B show an FFT image 900 and a graph 910 illustrating the steps S620 and S630 of FIG. 6.

Referring to FIG. 6, the computing device 300 (or the processor 320) may determine a threshold size for the pixel size of the second SEM image, at S610. The computing device 300 may transmit the determined threshold size to the SEM 100, and the SEM 100 may generate an SEM image such that the size of the pixel of the second SEM image is below the determined threshold size. According to one or more other embodiments, the threshold size of the pixel size of the SEM image may be determined by the SEM 100.

The threshold size of the pixel size of the SEM image may be determined based on the minimum size of the defect to be detected with the SEM 100 and/or on the size of the input electron beam of the SEM 100. For example, the threshold size may be determined proportional to the minimum size of the defect to be detected and/or the size of the input electron beam of the SEM 100.

Referring further to FIGS. 7 and 8, the threshold size may be determined based on a minimum size d1 of a defect 720 to be detected with the SEM 100, and a full width at half maximum d2 of the input electron beam 710 irradiated (emitted) onto the wafer 700. For example, the threshold size may be less than the sum d3 of the minimum size d1 of the defect 720 to be detected with the SEM 100 and the full width at half maximum d2 of the input electron beam 710. As shown in FIG. 7, it may be difficult to detect the defect 720 because the defect 720 is not included within the full width at half maximum d2 of the input electron beam 710, but when the threshold size of the pixel size is less than d3, at least part of the defect 720 is always included within the full width at half maximum d2 of the input electron beam 710 and the defect 720 is detectable.

The minimum size of the defect may be received from a user. For example, the computing device 300 may receive information related to the minimum size of the defect through an input/output interface (e.g., 340 of FIG. 3). According to one or more other embodiments, the minimum size of the defect may be determined to be the minimum size of a contact (e.g., width or length of the contact) formed on the surface of the first wafer may be determined.

Referring to FIGS. 6 and 9A, the computing device 300 (or the processor 320) may determine a scan direction of a wafer (e.g., a second wafer) based on the generated FFT image 900, at step S620. The computing device 300 may determine the scan direction of the wafer to be a first direction, when the number of peaks formed along the first direction (e.g., x direction) on the FFT image 900 is less than the number of peaks formed along a second direction (e.g., y direction) that intersects the first direction. For example, in the FFT image 900 of FIG. 9A, the scan direction of the wafer may be determined to be the y direction, because the number of peaks in the x direction is less than the number of peaks in the y direction. A peak may indicate a point in the FFT image where the signal intensity is higher than the signal intensity of the adjacent area by a predetermined ratio or more.

When the number of peaks formed along the first direction on the FFT image 900 and the number of peaks formed along the second direction intersecting the first direction are the same, the computing device 300 may arbitrarily determine the scan direction of the wafer to be either the first direction or the second direction. For example, when a regular pattern is found in both the first and second directions on the wafer on which a DRAM cell is formed, the scan direction of the wafer may be arbitrarily determined to be either the first or the second direction.

The SEM 100 may scan the wafer using the scan direction determined at step S620. For example, the SEM 100 may control the input electron beam so that the area irradiated (emitted) with the input electron beam is moved in a raster pattern having the scan direction determined at step S620 as a main scan direction, which may reduce aliasing, and reduce nuisance defects due to aliasing in the SEM image.

Referring back to FIG. 6, the computing device 300 (or the processor 320) may obtain n periods corresponding to n peaks (where, n is a natural number greater than or equal to 1) with reference to the determined scan direction on the generated FFT image, at step S630. For example, the computing device 300 may acquire n periods corresponding to n peaks in the order of an intensity of the n peaks based on the scan direction selected at step S620. According to one or more other embodiments, n peaks may be arbitrarily selected with respect to the scan direction, or n peaks may be selected in a direction starting from the peak closest to the origin and moving away.

For example, referring to FIG. 9B, the graph 910 may represent the FFT intensities of multiple peaks located on different x coordinates at any y point y1 of FIG. 9A, and the horizontal and vertical axes may be expressed in arbitrary units a.u. A plurality of peaks may correspond to a first-order peak, a second-order peak, a third-order peak, etc. based on magnitude of the relative intensity. The first-order peak may include information related to the overall shape of the pattern in the SEM image, and the second-order peak and subsequent peaks may include information related to the sharpness of the edge of the pattern in the SEM image. The peaks in the subsequent order after the second-order peak may be referred to as higher-order peaks. When n=1, the computing device 300 may obtain one period corresponding to the first-order peak, and when n=3, the computing device 300 may obtain three periods corresponding to each of the first-order peak, the second-order peak, and the third-order peak.

The computing device 300 (or the processor 320) may determine the size of the pixel of the SEM image to be a period that covers n periods and is less than the threshold size, at step S640. For example, the size of the pixel may be any one of common factors of n periods. In addition, the determined pixel size may be greater than the pixel size of the first SEM image. For example, when the n periods are 140 nm, 210 nm, and 280 nm, respectively, the common factors that may cover the n periods may be 70 nm, 35 nm, 17.5 nm, 10 nm, etc. which may cover all of the 140 nm, 210 nm, 280 nm period components. For example, a specific value that is multiplied by a specific natural number to produce each of the n periods may correspond to the common factor. When n=1, the common factor may represent one period. The computing device 300 may determine the size of the pixel of the SEM image to be a maximum value of the common factors, or a maximum value of the common factors less than a predetermined threshold size of the common factors.

The computing device 300 (or the processor 320) may generate the SEM image including a pixel of the determined size and detect a defect, at step S650. For example, the SEM image may be generated by the method 400 of FIG. 4.

The computing device 300 may calculate (obtain) a defect detection rate indicating a degree of the defects detected in the SEM image generated at step S650 compared to the defects detected in the SEM image generated at S510 and compare the calculated (obtained) result with the threshold (e.g., 70%), at step S660. For example, when 10 defects are found in the SEM image generated at step S510, and 8 defects are found in the SEM image generated at step S650, the defect detection rate may be calculated as 80%. Additionally, the defect detection rate may further include information related to an occurrence rate of false positives, which detects defects that were not detected at step S510.

When the defect detection rate is equal to or greater than a threshold at S660, the computing device 300 may determine the second size to be the size of the pixel determined at step S640, which is the size of the pixel of the second SEM image for the second wafer, at step S670. Accordingly, the aliasing may be reduced, and nuisance defects due to aliasing in the SEM image may be reduced.

According to one or more other embodiments, in response to determining that the defect detection rate is less than the threshold at step S660, the size of the pixel of the SEM image may be determined again at step S630. For example, when the defect detection rate is less than the threshold, the computing device 300 (or the processor 320) may further obtain a period corresponding to the next peak in order among n peaks, from the FFT image based on the determined scan direction, at step S630. The computing device 300 may determine the size of the pixel of the SEM image to be a period that is a common factor covering n+1 periods and is less than the threshold size, at step S640. The determined pixel size may be less than the period covering n periods, because the determined size of the pixel should cover more periods.

The pattern inspection system 1 may generate an SEM image including pixels of the determined size with respect to the first wafer and detect a defect, at step S650. The computing device 300 may calculate (obtain) the defect detection rate indicating the degree of the defects detected in the SEM image including pixels of the determined size compared to the defects detected in the SEM image generated at step S510, and compare the calculated result with a threshold, at S660. Steps S630 to S660 may repeat until the defect detection rate of the SEM image including pixels having a newly set size is equal to or greater than the threshold.

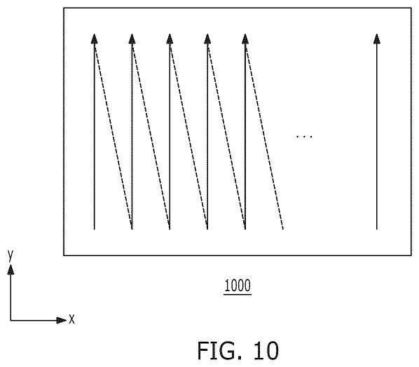

FIG. 10 is a diagram illustrating a scan direction of the wafer using the SEM. FIG. 10 illustrates an example of the scan direction by the electron beam on an arbitrary area 1000 on the wafer.

The scan direction of the wafer shown in FIG. 10 may be a direction determined at step S620 of FIG. 6, or based on the direction determined from the FFT image of FIG. 9A. The two-dimensional raster pattern may include a slow movement in the first direction (e.g., x direction) and a fast movement in the second direction (e.g., y direction), and the first direction may be referred to as a main direction and the second direction may be referred to as a sub direction. The scan may be performed in a combination of movement of the stage of an SEM (e.g., 60 in FIG. 1) and/or a scan by a deflector (e.g., 30 in FIG. 1). For example, the scan in the main direction may be performed by the stage movement, and the scan in the sub direction may be performed using the deflector. In FIG. 9A, as the scan direction is determined to be the x direction, the scan of the wafer may be performed using a raster pattern having the x direction as the main direction. Accordingly, the aliasing phenomenon may be reduced, and the nuisance defects due to aliasing in the SEM image may be reduced.

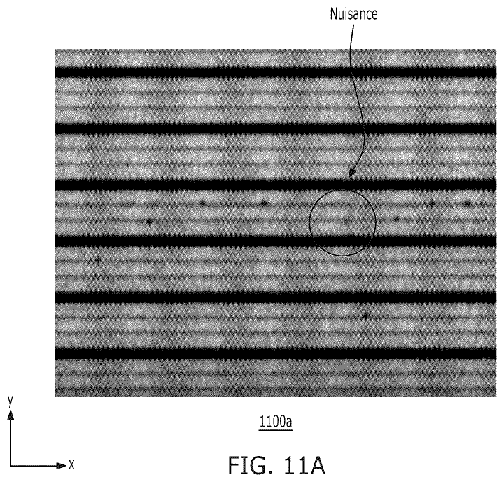

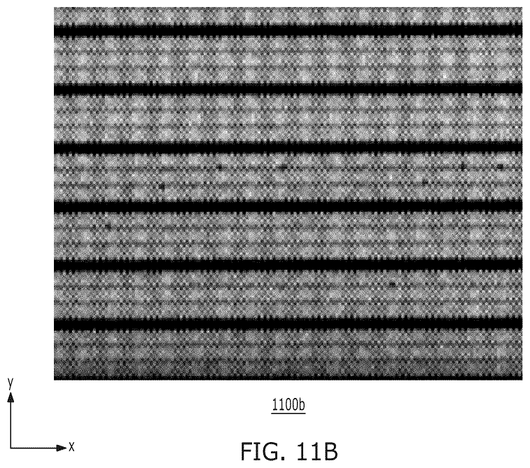

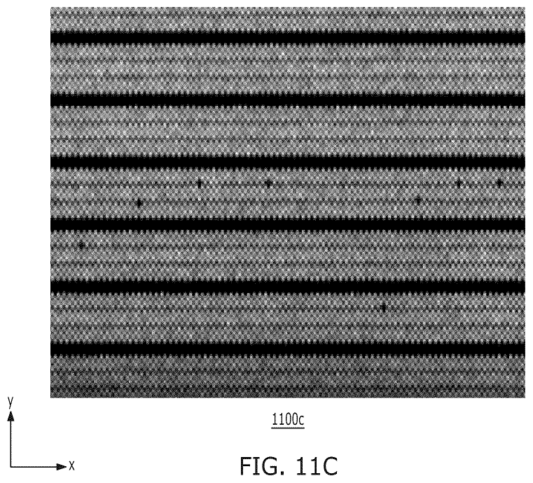

FIGS. 11A to 11C are diagrams illustrating SEM images 1100a, 1100b, and 1100c including different pixel sizes. Each of the SEM images 1100a, 1100b, and 1100c is generated for the same area of the wafer by varying only the size of the pixel.

FIG. 11A illustrates the SEM image 1100a generated based on a randomly selected pixel size (e.g., 70 nm). In FIG. 11A, it may be seen that a nuisance defect has occurred due to aliasing because the period of the pattern formed on the wafer is not taken into account.

FIG. 11B illustrates an SEM image 1100b generated based on an arbitrarily selected pixel size (e.g., 80 nm). FIG. 11B suggests that as the pixel size increases, the resolution decreases, so that the image is blurred, and it may be more difficult to clearly detect the defects on the wafer. In addition, since the period of the pattern formed on the wafer is not taken into account, the possibility of occurrence of nuisance defects due to aliasing cannot be excluded.

FIG. 11C illustrates the SEM image 1100c generated based on a pixel size 72.8 nm determined based on a period of a pattern extracted using an FFT image according to one or more embodiments. In the SEM image 1100c of FIG. 11C, unlike the SEM images 1100a and 1100b of FIGS. 11A and 11B, defects formed on the wafer are more clearly visible, and no nuisance defects due to aliasing are shown.

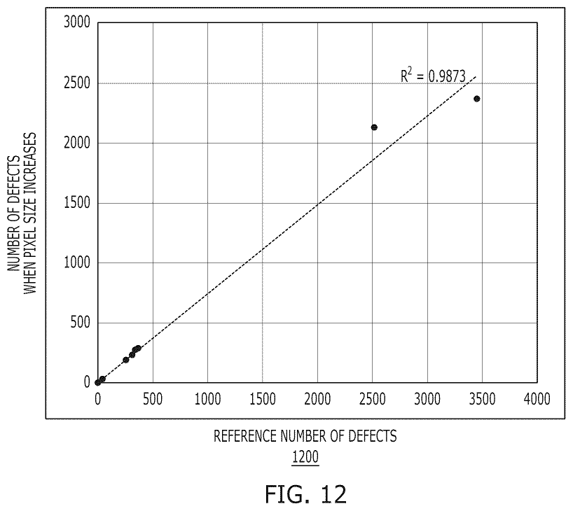

FIG. 12 is a graph 1200 comparing the number of defects before and after determining the pixel size. Each point on the graph 1200 represents the reference number of defects for a specific area of the wafer and the number of defects determined based on the increased pixel size (e.g., 72.8 nm). The reference number of defects may refer to the number of defects determined using the SEM image generated using the existing pixel size (e.g., 35 nm) before the pixel size is determined.

The defect detection process is performed on the same wafer and performed in 3.5% of the total area of the wafer. When the pixel size increases, the total number of defects is about 76% of the original total number of defects, and the throughput is calculated (obtained) to be 25.5 times throughput of generating an SEM image using the existing pixel size. For example, by increasing the pixel size, the detection rate may be slightly lowered, but the throughput is significantly increased.

The present disclosure is not limited to the aspects described above and the accompanying drawings, and various forms of substitution, modification, and change will be possible by those of ordinary skill in the art without departing from the technical idea of the present disclosure, which also fall within the scope of the present disclosure. For example, one or more steps in the process illustrated and described with reference to FIGS. 5 and 6 may be omitted, the order of each of the operations may be changed, one or more operations may be temporally overlapped, or one or more operations may be repeatedly performed several times.

While embodiments have been described with reference to the figures, it will be understood by those of ordinary skill in the art that various changes in form and details may be made therein without departing from the spirit and scope as defined by the following claims and their equivalents.

What is claimed is:

1. A pattern inspection system, comprising:
a scanning electron microscope (SEM) comprising:
an electron gun configured to generate a first electron beam and emit the generated first electron beam toward a first wafer;
a detector configured to detect electrons emitted from the first wafer based on the first electron beam emitted toward the first wafer; and
at least one processor configured to:
generate a first SEM image comprising a plurality of pixels based on the detected electrons; and
determine, based on a period of a pattern extracted from the first SEM image, a pixel size of a second SEM image to be generated by the SEM with respect to a second wafer.

2. The pattern inspection system according to claim 1, wherein: the at least one processor is further configured to transmit the determined pixel size to the SEM, and
the SEM is configured to:
generate a second electron beam;
emit the generated second electron beam toward the second wafer, and
detect electrons emitted from the second wafer based on the second electron beam emitted toward the second wafer, and
generate the second SEM image having the determined pixel size.

3. The pattern inspection system according to claim 1, wherein: the SEM is further configured to generate the first SEM image by controlling the first electron beam so that an area on the first wafer emitted by the first electron beam is moved along a scan direction, and
the at least one processor is further configured to:
generate a Fast Fourier Transform (FFT) image by performing two-dimensional FFT (2D FFT) on the first SEM image; and
determine, based on the generated FFT image, a scan direction of the second wafer to be a first direction.

4. The pattern inspection system according to claim 3, wherein the SEM is further configured to:
generate a second electron beam;
emit the generated second electron beam toward the second wafer; and
generate the second SEM image by controlling the second electron beam so that the area on the second wafer emitted with the second electron beam is moved in a raster pattern that has the first direction as a main direction.

5. The pattern inspection system according to claim 3, wherein the at least one processor is further configured to determine, based on a number of peaks formed along the first direction on the generated FFT image being less than a number of peaks formed along a second direction intersecting the first direction, the scan direction of the second wafer to be the first direction.

6. The pattern inspection system according to claim 3, wherein the at least one processor is further configured to determine, based on a number of peaks formed along the first direction on the generated FFT image and a number of peaks formed along a second direction intersecting the first direction are the same, the scan direction of the second wafer to be the first direction or the second direction.

7. The pattern inspection system according to claim 3, wherein the at least one processor is further configured to:
extract, from the generated FFT image, one or more periods corresponding to one or more peaks in an order of an intensity of each of the one or more peaks along the first direction; and
determine a first period that is any one of common factors of the extracted one or more periods and greater than a pixel size of the first SEM image,
wherein the SEM is further configured to:
generate a second electron beam;
emit the generated second electron beam toward the first wafer; and
generate, by detecting electrons emitted from the first wafer based on the second electron beam emitted onto the first wafer, a third SEM image comprising a pixel of a size corresponding to the first period,
wherein the at least one processor is further configured to determine, based on a first defect detection rate, the pixel size of the second SEM image, and
wherein the first defect detection rate is a rate of a number of defects detected in the third SEM image compared to a number of defects detected in the first SEM image.

8. The pattern inspection system according to claim 7, wherein the at least one processor is further configured to determine, based on the first defect detection rate being equal to or greater than a threshold, the pixel size of the second SEM image to correspond to the first period.

9. The pattern inspection system according to claim 7, wherein the at least one processor is further configured to:
extract, based on the first defect detection rate being less than a threshold, a period corresponding to a second peak having an intensity that is the second highest of the one or more peaks on the generated FFT image along the first direction; and
determine a second period that is any one of common factors of the one or more periods, the extracted period corresponding to the second peak and being greater than the pixel size of the first SEM image,
wherein the SEM is further configured to:
generate a third electron beam;
emit the third electron beam onto the first wafer; and
generate, by detecting electrons emitted from the first wafer based on the third electron beam emitted onto the first wafer, a fourth SEM image comprising a pixel having a size corresponding to the second period,
wherein the at least one processor is further configured to determine, based on a second defect detection rate being equal to or greater than the threshold, the pixel size of the second SEM image to be a pixel size of the fourth SEM image, and
wherein the second defect detection rate is a rate of a number of defects detected in the fourth SEM image compared to the number of defects detected in the first SEM image.

10. The pattern inspection system according to claim 7, wherein the first period corresponds to a maximum value of the common factors.

11. The pattern inspection system according to claim 7, wherein the first period corresponds to a maximum value of common factors less than a threshold period among the common factors of the extracted one or more periods.

12. The pattern inspection system according to claim 1, wherein the at least one processor is further configured to determine the pixel size of the second SEM image to be less than a threshold size.

13. The pattern inspection system according to claim 12, wherein the at least one processor is further configured to determine, based on a minimum size of a defect to be detected by the SEM, the threshold size.

14. The pattern inspection system according to claim 13, wherein the at least one processor is further configured to:
receive the minimum size of the defect; and
determine the threshold size in proportion to the received minimum size of the defect.

15. The pattern inspection system according to claim 13, wherein the at least one processor is further configured to:
determine the minimum size of the defect to be a minimum size of a contact formed on a surface of the first wafer; and
determine the threshold size in proportion to the determined minimum size of the defect.

16. The pattern inspection system according to claim 12, wherein the at least one processor is further configured to determine the threshold size in proportion to a size of an electron beam generated by the SEM.

17. The pattern inspection system according to claim 12, wherein the at least one processor is further configured to determine, based on a minimum size of a defect to be detected using the SEM and a full width at half maximum (FWHM) of an electron beam of the SEM, the threshold size.

18. A computing device, comprising:
a memory configured to store one or more instructions; and
at least one processor configured to execute the one or more instructions stored in the memory to:
receive a first scanning electron microscope (SEM) image from a scanning electron microscope configured to detect electrons emitted from a first wafer based on electron beam being emitted onto the first wafer;
generate a first SEM image comprising a plurality of pixels based on the detected electrons; and
determine, based on a period of a pattern extracted from the first SEM image, a pixel size of a second SEM image with respect to a second wafer to be generated by the SEM.

19. A method of pattern inspection, the method being executed by at least one processor, the method comprising:
receiving a first scanning electron microscope (SEM) image from a scanning electron microscope configured to detect electrons emitted from a first wafer based on first electron beam being emitted onto the first wafer;
generating a first SEM image comprising a plurality of pixels based on the detected electrons; and
determining, based on a period of a pattern extracted from the first SEM image, a pixel size of a second SEM image with respect to a second wafer to be generated by the SEM.

20. The method according to claim 19, further comprising transmitting the determined pixel size to the SEM,
wherein the SEM is further configured to:
emit a second electron beam onto the second wafer; and
generate, by detecting electrons emitted from the second wafer based on the second electron beam being emitted onto the second wafer, the second SEM image having the determined pixel size.
